(19) United States
(12) Patent Application Publication
(10) Pub. No.: US 2007/0275531 A1
(43) Pub. Date: Nov. 29, 2007

(54) METHOD OF MANUFACTURING FLASH MEMORY DEVICE

(75) Inventor: Byung Soo Park, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/618,709

(22) Filed: Dec. 29, 2006

(30) Foreign Application Priority Data
May 29, 2006 (KR) 2006-48231

(51) Int. Cl. H01L 21/336

(52) U.S. Cl. 438/299

(57) ABSTRACT

A method of manufacturing a flash memory device includes forming a gate over a semiconductor substrate in which a cell region, a low voltage region and a high voltage region are defined. First ions are implanted into the cell region to form doped junctions in the cell region, the low voltage region and the high voltage region being covered to prevent the first ions from being implanted into the low voltage region and the high voltage region. The first ions implanted into the cell region are activated using a rapid annealing process. The rapid annealing process is performed for no more than 10 minutes. The rapid annealing process minimizes an occurrence of Transient Enhanced Diffusion at the cell region.

### CROSS-REFERENCES TO RELATED APPLICATIONS

The present application claims priority to Korean patent application number 10-2006-48231, filed on May 29, 2006, which is incorporated by reference in its entirety.

### BACKGROUND OF THE INVENTION

The present invention relates to flash memory devices and, more particularly, to a method of manufacturing a flash memory device, which can prevent a punch-through leakage current occurring between cell junction units.

As the level of integration of flash memory devices increases, the cell size gradually decreases. In particular, in the case of a cell having the gate length of 100 nm or less, a punch-through leakage current can be generated due to a small gate length, thus degrading the sensing margin required for the accuracy of a cell.

FIG. 1 is a graph illustrating the V-I characteristics of a cell with and without punch-through. The X-axis indicates the gate voltage in an arbitrary unit. The Y-axis indicates the drain current in ampere.

In FIG. 1, curve A indicates the variation of drain current with respect to gate voltage in a cell with a gate length of about 100 nm. As indicated by the curve A, a normal drain current (Id) is obtained with respect to an applied gate voltage Vg, and punch-through is not generated.

A curve B shows the punch-through leakage current in a cell having a reduced gate length. The drain current (Id) with respect to the applied gate voltage Vg is higher than the normal value (shown by curve A). The leakage current decreases the sensing margin of a cell and also causes a variety of errors when the cell is evaluated in a memory development stage.

Therefore, in order to improve cell characteristics, the punch-through leakage current needs to be eliminated. One way to do this is to increase the effective channel length. Current methods use a reduced ion dose during the ion implantation process to obtain an effective channel length. However, this method decreases the amount of current flowing through the cell itself. In particular, when the resistance of the cell junction is high due to a reduction in ion dose, the amount of current flowing through the cell itself is further decreased.

Further, ions implanted during the cell junction formation process is activated through an annealing process that is subsequently performed, thus generating Transient Enhanced Diffusion (TED) and degrading the channeling doping profile. TED refers to an unintended clustering of dopants at regions that were damaged by the implantation process.

In the case of a cell having a long gate length, the concentration of boron (B) is not significantly lowered because an effective channel length can be maintained despite the occurrence of TED. This is possible because there are sufficient dopants in the channel. In the case of a cell having a short gate length, the decrease in the concentration of boron (B) due to the occurrence of TED cannot be effectively compensated.

### BRIEF SUMMARY OF THE INVENTION

The present invention is directed towards a method of manufacturing a flash memory device, in which a punch-through leakage current in a short gate length transistor may be prevented from occurring between cell junction units.

In one embodiment, a method of manufacturing a flash memory device includes the steps of; forming a gate over a semiconductor substrate in which a cell region, a low voltage region and a high voltage region are defined; performing an ion implantation process with only the cell region being opened and forming cell junctions in the semiconductor substrate; performing a first thermal treatment process; performing a low concentration ion implantation process with only the low voltage region being opened; performing an ion implantation process with only the high voltage region being opened; forming a spacer on sidewalls of the gate and performing a high concentration ion implantation process with only the low voltage region being opened; and performing a second thermal treatment process.

In another embodiment, a method of manufacturing a flash memory device includes the steps of; forming a gate over a semiconductor substrate in which a cell region, a low voltage region and a high voltage region are defined; performing an ion implantation process with only the cell region being opened and forming cell junctions in the semiconductor substrate; performing a low concentration ion implantation process with only the low voltage region being opened; performing an ion implantation process with only the high voltage region being opened; forming a spacer on sidewalls of the gate and performing a high concentration ion implantation process with the low voltage region being opened; and performing a Rapid Thermal Annealing (RTA) process.

In one embodiment, a method of manufacturing a flash memory device includes forming a gate over a semiconductor substrate in which a cell region, a low voltage region and a high voltage region are defined. First ions are implanted into the cell region while covering the low voltage region and the high voltage region to form cell junctions in the semiconductor substrate. Second ions are implanted into the low voltage region while covering the cell region and the high voltage region, the implanting-second-ions step being a low concentration ion implantation process. Third ions are implanted into the high voltage region while covering the cell region and the low voltage region. A spacer is formed on sidewalls of the gate. Fourth ions are implanted into the low voltage region, the implanting-fourth-ions step being a high concentration ion implantation process. A Rapid Thermal Annealing (RTA) process is performed after the implanting-fourth-ions step.

In one embodiment, a method of manufacturing a flash memory device includes forming a gate over a semiconductor substrate in which a cell region, a low voltage region and a high voltage region are defined. First ions are implanted into the cell region to form doped junctions in the cell region, the low voltage region and the high voltage region being covered to prevent the first ions from being implanted into the low voltage region and the high voltage region. The first ions implanted into the cell region are activated using a rapid annealing process. The rapid annealing process is performed for no more than 10 minutes. The rapid annealing process minimizes an occurrence of Transient Enhanced Diffusion at the cell region.

In another embodiment, the method further comprises implanting second ions into the low voltage region while covering the cell region and the high voltage region, so that the second ions are not implanted into the cell region and the high voltage region. Third ions are implanted into the high voltage region while covering the cell region and the low voltage region, so that the third ions are not implanted into the cell region and the low voltage region. The rapid annealing process activates at least the first ions and the second ions.

In another embodiment, the method further includes implanting fourth ions into the low voltage region while covering the cell region and the high voltage region, so that the fourth ions are not implanted into the cell region and the low voltage region; and performing a thermal treatment process to activate at least the fourth ions. The thermal treatment process activates the third ions as well.

### BRIEF DESCRIPTION OF THE DRAWINGS

FIG. 1 is a graph illustrating the V-I characteristics of a cell with and without punch-through.

FIGS. 2A to 2C are cross-sectional views illustrating a method of manufacturing a flash memory device according to an embodiment of the present invention.

FIG. 3 is a graph illustrating the channel boron concentration profile when the existing process and a RTA are performed.

FIG. 4 is a graph illustrating variation in the V-I characteristics of a cell when the existing process and a RTA are performed.

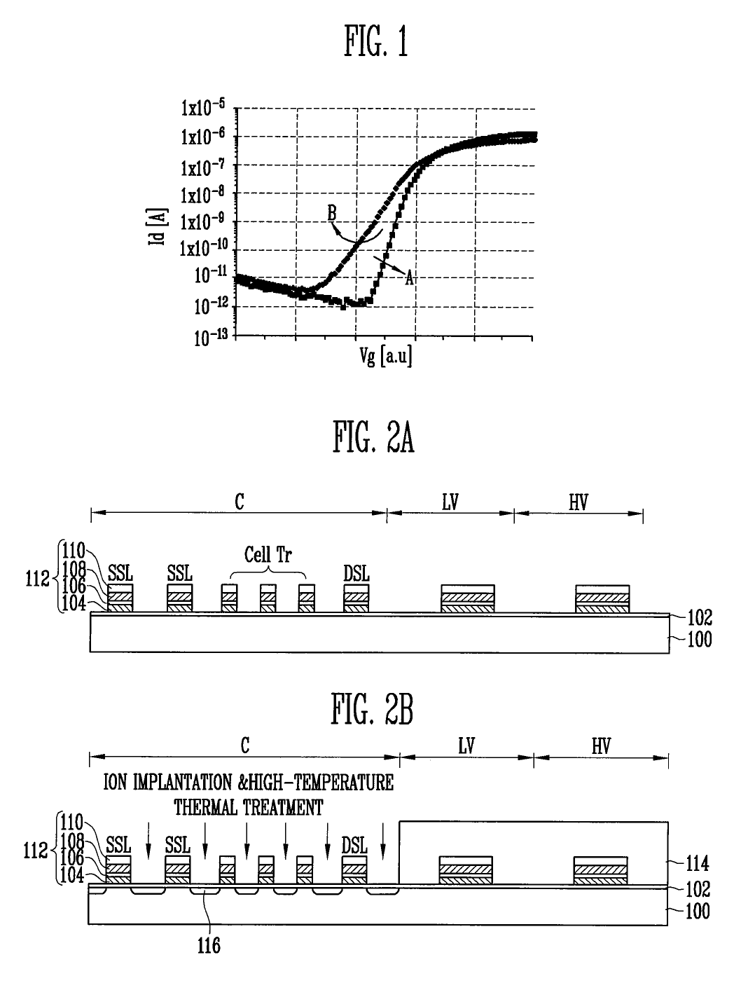

### DESCRIPTION OF SPECIFIC EMBODIMENTS

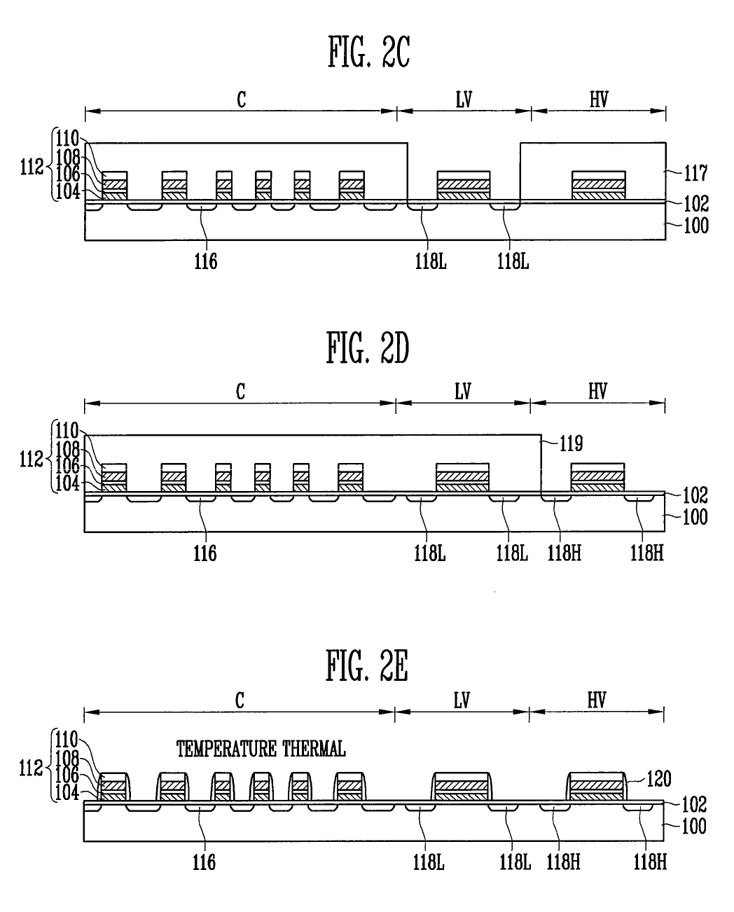

Referring to FIG. 2A, a Vt ion implantation process is performed on a semiconductor substrate 100 having a cell region and a peripheral region. The peripheral region is a region provided at a periphery of the cell region and includes a low voltage region LV or a high voltage region HV, or both. FIG. 2A shows a cell region C a low voltage region LV and a high voltage region HV that are defined in order to control the threshold voltage Vt. The Vt ion implantation process includes implanting boron (B) ions in the present implementation. Dopants other than boron may be used in other implementations.

A tunnel oxide layer 102 (or tunnel dielectric layer) is formed on the semiconductor substrate 100. A conductive layer 104 for the floating gates, a dielectric layer 106, and conductive layers 108, 110 for the control gates are formed. The conductive layer 104 for a floating gate may include polysilicon and the dielectric layer 106 may include an Oxide-Nitride-Oxide (ONO) structure. The conductive layers for control gates may include polysilicon and tungsten (or metal). For example, the conductive layer 108 may be a polysilicon layer, and the conductive layer 110 may be a tungsten layer 110. A gate structure 112 is comprised of the conductive layer 104 (or first polysilicon layer), the dielectric layer 106, the conductive layer 108 (or the second polysilicon layer), and the conductive layer 110.

Referring to FIG. 2B, a first photoresist pattern 114 is formed over the low voltage region LV and the high voltage region HV while keeping the cell region C is open. An ion implantation process is carried out using the gate structure 112 as a mask to form cell junctions 116 in the semiconductor substrate 100. The ion implantation process can be performed using phosphor (P) and/or arsenic (As) source to form junction regions.

After the first photoresist pattern 114 is removed, a rapid thermal annealing (RTA) process is performed in order to activate the implanted ions. The implanted ions are phosphor (P) and/or arsenic (As) in the present implementation. The RTA can be performed in a temperature range of 800 to 1200 degrees Celsius for 1 second to 10 minutes. In order to control the diffusion of the ions into the semiconductor substrate 100 during the RTA process, a ramp-up method is employed. The ramp-up rate is set in the range of 10 to 150 degrees Celsius/sec.

Referring to FIG. 2C, a second photoresist pattern 117 is formed over the high voltage region HV and the cell region C while keeping the low voltage region LV is open. A low concentration ion implantation process is implanted with the low voltage region LV being open while covering the high voltage region HV and the cell region C. The low concentration ion implantation process is performed using phosphor (P) and/or arsenic (As). The implantation energy used is 20 to 70 keV. The low concentration implantation step forms a junction 118L. The junction 118L has a concentration of 1E12 to 1E14 ions/cm².

Referring to FIG. 2D, the second pohotoresist pattern 117 is removed. A third photoresist pattern 119 is formed over the cell region C and the low voltage region LV while keeping the high voltage region HV is open. An ion implantation process is performed with the high voltage region HV being open while covering the cell region C and the low voltage region LV. The ion implantation process is performed using phosphor (P). The implantation energy used is 20 to 100 keV. The implantation step forms a junction 118H. The junction 118H has a concentration of 1E12 to 1E14 ions/cm².

Referring to FIG. 2E, the third photoresist pattern 119 is removed. An insulating layer is formed over the substrate after the high voltage region has been implanted with the ions. The insulating layer is etched to form a spacer 120 on the sides of the gate 112. The low voltage region LV is open while the cell region C and the high voltage region HV are covered. A high concentration ion implantation process is performed on the low voltage region LV using the gate 112 and the spacer 120 as masks to form a lightly-doped drain (LDD) structure within the semiconductor substrate 100.

In order to activate the implanted ions, a furnace type thermal treatment process is performed. As used herein, the low concentration ion implantation process and the high concentration ion implantation process are used as relative terms. That is, the low concentration ion implantation process provides a lower ion concentration than the high concentration ion implantation process.

In one embodiment, the RTA process is performed prior to the furnace type thermal treatment process. Otherwise, the effects of the RTA process are lost if the RTA process is performed after the furnace type thermal treatment process. The RTA process, e.g., to drive the implanted ions, inhibits the occurrence of TED. If the furnace anneal is performed first, then TED has already occurred on the substrate. Accordingly, the use of RTA process is less effective in inhibiting TED.

In another embodiment of the present invention, the RTA process is not performed after the cell junctions 116 are formed. A high concentration ion implantation process is performed on the low voltage region LV without performing the RTA process after the cell junctions 116 are formed. Then the RTA process is performed instead of the furnace type thermal treatment process.

As a result, ions implanted into the junction regions as well as the cell region C and the low voltage region LV and the high voltage region HV are activated. Furthermore, since process steps are not increased, Turn Around Time (TAT) is not lengthened.

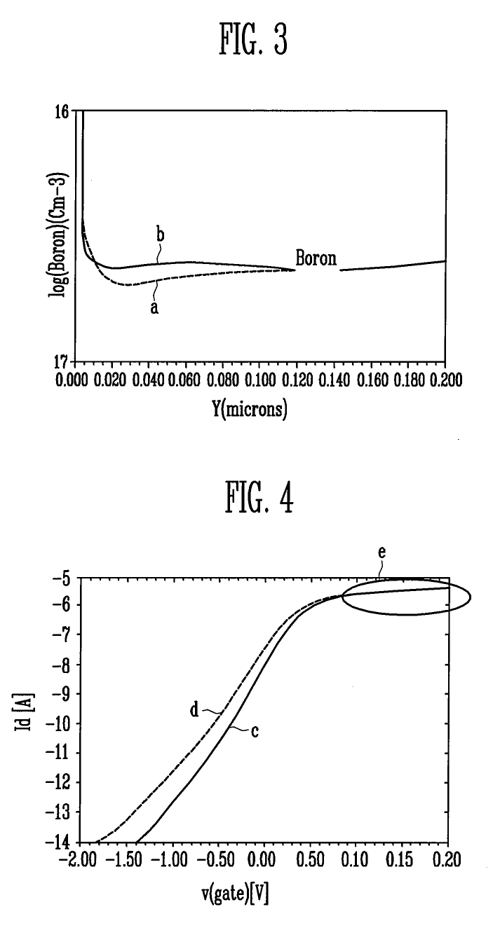

In FIG. 3, “a” is a plot showing the concentration of boron (B) with respect to junction depth when the existing process is applied, i.e., when the furnace anneal is used to drive the ions. A plot “b” shows the concentration of boron (B) with respect to junction depth when the RTA process is applied is used to drive the ions.

From FIG. 3, it can be seen that a reduction in the concentration of boron (B) in a region in which TED occurs is largely prevented in the case (“b”) where the RTA process is applied than the case (“a”) where the existing process is applied. As a result, the RTA process provides better characteristics in preventing the punch-through leakage current.

Referring to FIG. 4, “c” is a plot showing the drain current Id with respect to an applied gate voltage Vg when the RTA process is applied, and “d” is a plot showing the drain current Id with respect to an applied gate voltage Vg when the existing process is applied.

From FIG. 4, it can be seen that “c” and “d” have the same current value at “e”. The punch-through leakage current is more likely to occur with the occurrence of TED since it would remove the dopants from cell channel region. With the use of the RTA process to activate the ions, the occurrence of TED is inhibited. As a result the dopants are not removed from the cell channel region.

As described above, according to the present invention, after the cell junction is formed, the RTA process is performed to minimize the occurrence of TED. This enables the channel region to maintain a sufficient number of dopants to effectively function as a channel.

The above embodiments of the present invention are illustrative and not limitative. Various alternatives and equivalents are possible. Other additions, subtractions, or modifications are obvious in view of the present disclosure and are intended to fall within the scope of the appended claims.

What is claimed is:

1. A method of manufacturing a flash memory device, the method comprising:
forming a gate over a semiconductor substrate in which a cell region, a low voltage region and a high voltage region are defined;
performing an ion implantation process with the cell region being opened while covering the low voltage region and the high voltage region to form cell junctions in the semiconductor substrate;
performing a first thermal treatment process of the substrate after the cell region has been implanted with ions, the first thermal treatment process being performed for no more than 10 minutes;
performing a low concentration ion implantation process on the low voltage region while covering the cell region and the high voltage region;
implanting ions into the high voltage region while covering the cell region and the low voltage region;
forming a spacer on sidewalls of the gate;
performing a high concentration ion implantation process on the low voltage region being opened; and
performing a second thermal treatment process after the high concentration ion implantation process.

2. The method of claim 1, wherein:
the first thermal treatment process is a rapid thermal annealing (RTA) process, and
the second thermal treatment process is a furnace-type thermal treatment process.

3. The method of claim 1, wherein the first thermal treatment process is performed in a temperature range of 800 to 1200 degrees Celsius for 1 second to 10 minutes

4. The method of claim 1, wherein the first thermal treatment process employs a ramp-up method, and the ramp-up ratio is set in the range of 10 to 150 degrees Celsius/sec.

5. A method of manufacturing a flash memory device, the method comprising:
forming a gate over a semiconductor substrate in which a cell region, a low voltage region and a high voltage region are defined;
implanting first ions into the cell region while covering the low voltage region and the high voltage region to form cell junctions in the semiconductor substrate;
implanting second ions into the low voltage region while covering the cell region and the high voltage region, the implanting-second-ions step being a low concentration ion implantation process;
implanting third ions into the high voltage region while covering the cell region and the low voltage region;
forming a spacer on sidewalls of the gate;
implanting fourth ions into the low voltage region, the implanting-fourth-ions step being a high concentration ion implantation process; and
performing a Rapid Thermal Annealing (RTA) process after the implanting-fourth-ions step to activate the ions.

6. The method of claim 5, wherein the RTA process is performed in a temperature range of 800 to 1200 degrees Celsius for 1 second to 10 minutes

7. The method of claim 5, wherein the RTA process employ a ramp-up method, and the ramp-up ratio is set in the range of 10 to 150 degrees Celsius/sec.

8. The method of claim 5, wherein the implanting-fourth-ions step is performed while covering the cell region and the high voltage region.

9. A method of manufacturing a flash memory device, the method comprising:
forming a gate over a semiconductor substrate in which a cell region, a low voltage region and a high voltage region are defined;
implanting first ions into the cell region to form doped junctions in the cell region, the low voltage region and the high voltage region being covered to prevent the first ions from being implanted into the low voltage region and the high voltage region; and
activating the first ions implanted into the cell region using a rapid annealing process.

10. The method of claim 9, wherein the rapid annealing process is performed for no more than 10 minutes.

11. The method of claim 9, wherein the rapid annealing process minimizes an occurrence of Transient Enhanced Diffusion at the cell region.

12. The method of claim 9, further comprising:
implanting second ions into the low voltage region while covering the cell region and the high voltage region, so that the second ions are not implanted into the cell region and the high voltage region; and
implanting third ions into the high voltage region while covering the cell region and the low voltage region, so that the third ions are not implanted into the cell region and the low voltage region.

13. The method of claim 12, the method further comprising:
implanting fourth ions into the low voltage region while covering the cell region and the high voltage region, so that the fourth ions are not implanted into the cell region and the low voltage region; and
performing a thermal treatment process to activate at least the fourth ions.

14. The method of claim 13, wherein the thermal treatment process activates the third ions.

15. The method of claim 12, wherein the rapid annealing process activates at least the first ions and the second ions.
